(19) United States
(12) Patent Application Publication
(10) Pub. No.: US 2014/0002966 A1
(43) Pub. Date: Jan. 2, 2014

(54) ELECTRONIC DEVICE FOR SCANNING

(71) Applicant: CHUN-KUEI LU, Tu-Cheng (TW)

(72) Inventor: CHUN-KUEI LU, Tu-Cheng (TW)

(73) Assignee: HON HAI PRECISION INDUSTRY CO., LTD., Tu-Cheng (TW)

(21) Appl. No.: 13/554,105

(22) Filed: Jul. 20, 2012

(30) Foreign Application Priority Data
Jun. 29, 2012 (TW) 101123437

(51) Int. Cl. H05K 5/03

(52) U.S. Cl. 361/679.01

(57) ABSTRACT

An electronic device includes a base and a cover rotatably secured to the base. The base includes a supporting board and a positioning portion. The positioning portion is located on one side of the supporting board. The positioning portion abuts the supporting board and is elastically deformable to disengage from the supporting board. The cover abuts the supporting board and is rotatable relative to the base to disengage from the supporting board.

### BACKGROUND

1. Technical Field

The present disclosure relates to electronic device, and particularly to an electronic device for scanning an object.

2. Description of Related Art

Scanning machines include a scanning base and a cover rotatably secured to the base. When a user wants to scan files, the cover will be firstly lifted, and then a required scanning file is placed on the base. Lastly, the cover is closed to press the scanning file, the scanning file will be driven by airflow generated between the base and the cover, so that the original position of the scanning file may be changed to distort the scanned image.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of an electronic device, and the electronic device comprising a base and a cover.

FIG. 2 is an assembled view of FIG. 1, but the cover is unlocked.

FIG. 3 is an enlarged view of a circle portion III of FIG. 2.

FIG. 4 is another assembled view of FIG. 1, but the cover is closed.

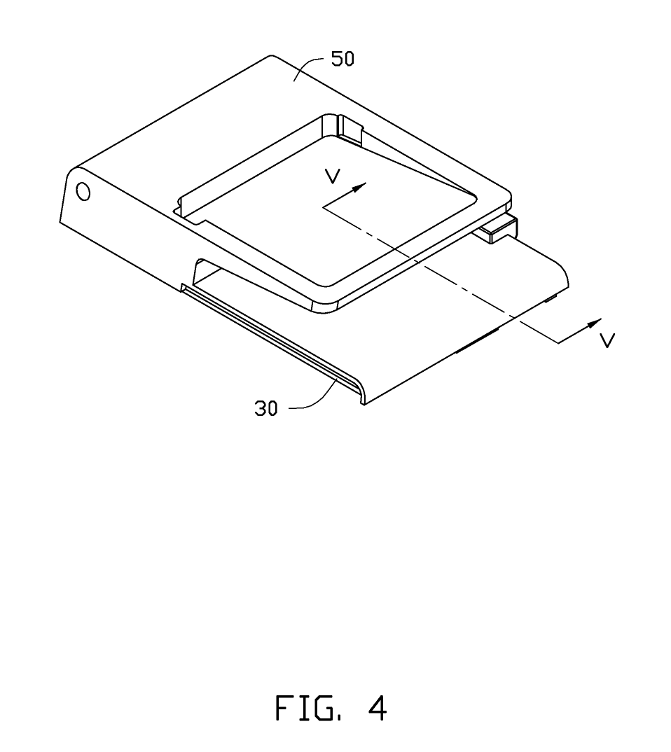

FIG. 5 is a cross-sectional view of the electronic device of FIG. 4, taken along the line V-V.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

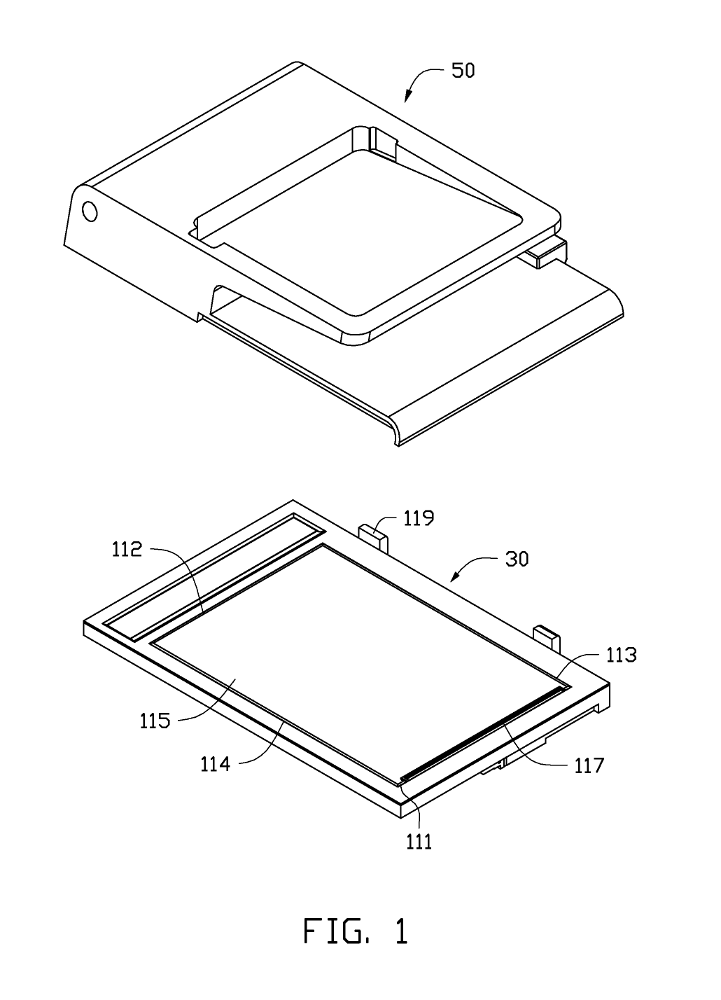

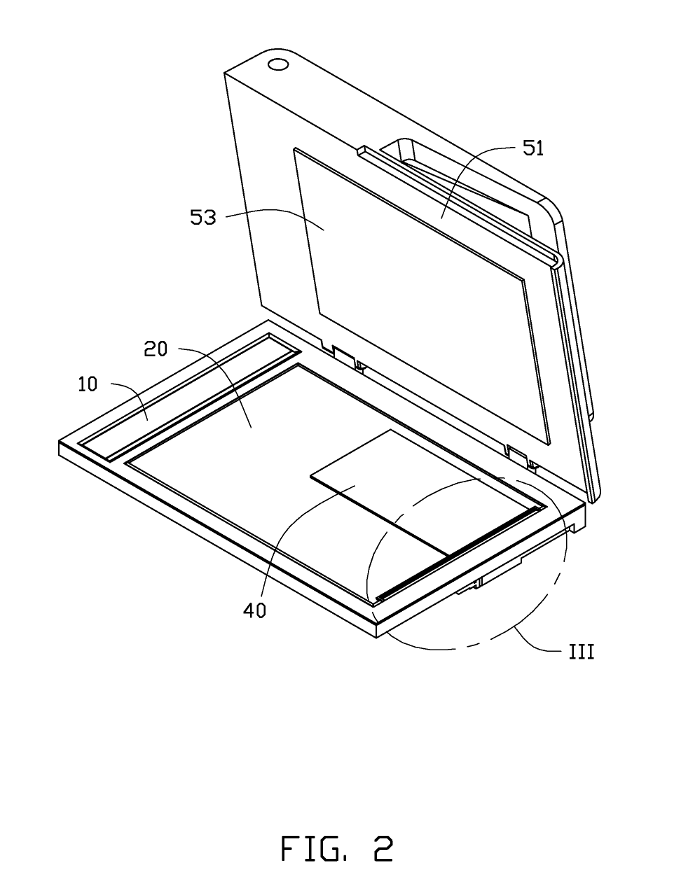

FIGS. 1-2 show an electronic device in accordance with an embodiment. The electronic device includes a base 30 and a cover 50 rotatably secured to the base 30. The electronic device may be a scanning machine.

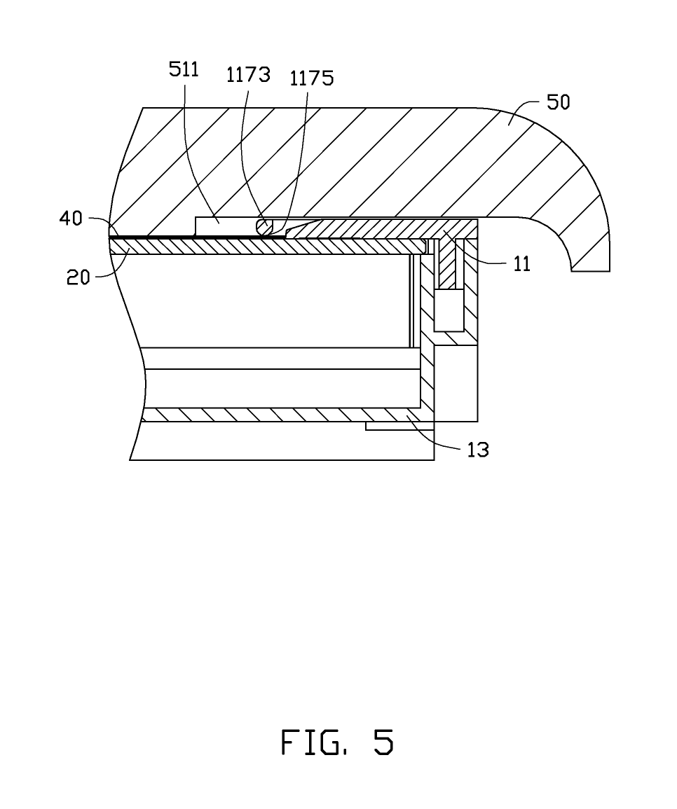

The base 30 includes a basic portion 10 and a supporting board 20 installed on the basic portion 10. The basic portion 10 includes a first base plate 11 and a second base plate 13 (shown in FIG. 5). An opening 115 is defined in a center of the first base plate 11. A positioning portion 117 is located on a first sidewall 111 of the opening 115. In one embodiment, the positioning portion 117 may be located on a second sidewall 112, a third sidewall 113, or a fourth sidewall 114 of the opening 115; and the first sidewall 111, a second sidewall 112, a third sidewall 113, and the fourth sidewall are all inclined planes relative to the first base plate 11.

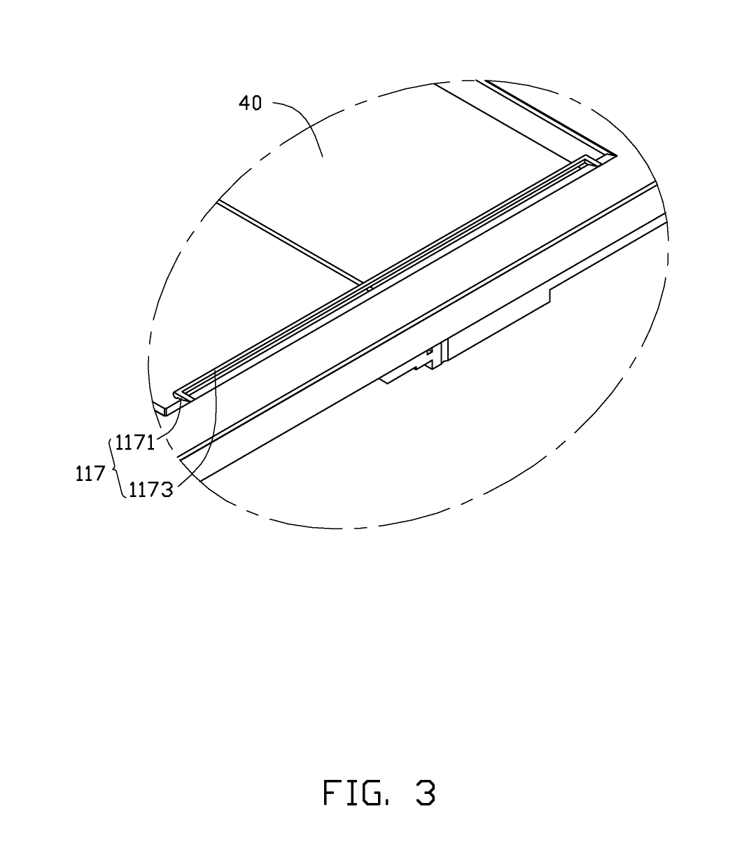

Referring to FIG. 3, the positioning portion 117 includes two resilient arms 1171 and a pressing portion 1173 connected to the two resilient arms 1171. In one embodiment, the positioning portion 117 is made of plastic material. The two resilient arms 1171 extend upwards from the first sidewall 111 of the opening 115. The pressing portion 1173 has a cross-section parallel to the supporting board 20. In one embodiment, an area size of the cross-section of the pressing portion 1173 is smaller than an area size of supporting board 20. The pressing portion 1173 includes a pressing surface 1175 protruding towards the supporting board 20. The pressing surface 1175 is substantially arc-shaped. The pressing surface 1175 is configured to press an object 40 when the electronic device is used to scan a file. Two mounting portion 119 (shown in FIG. 1) are located on an outside edge of the first base plate 11. The two mounting portion 119 are capable of securing the cover 50.

Referring to FIG. 5, the supporting board 20 is installed between the first base plate 11 and the second base plate 13. The supporting board 20 is placed below the opening 115 and configured to support the object 40. In one embodiment, the supporting board 20 is made of glass material.

Referring to FIGS. 2 and 5, the cover 50 includes a body 51 and a pressing piece 53. The body 51 defines a receiving slot 511 corresponding to the positioning portion 117. The positioning portion 117 is capable of being received in the receiving slot 511 when the cover 50 is covered. The pressing piece 53 is secured to an inner side of the body 51. The pressing piece 53 extends through the opening 115 to press the object 40 on the supporting board 20. The pressing piece 53 is substantially rectangular.

In assembly, the cover 50 is secured to the base 30 via the two mounting portion 119.

In use, the pressing portion 1173 is lifted up to deform the two resilient arms 1171. The object 40 is placed on the supporting board 20, and a part of the object 40 is located below the pressing portion 1173. The two resilient arms 1171 elastically return, and the pressing surface 1175 presses the object 40 for preventing the object 40 from moving relative to the supporting board 20. The cover 50 is rotated relative to the base 30 to press the object 40. During the process of closing the cover 50, the original position of the object 40 relative to the supporting board will not be changed by the airflow generated between the cover 50 and the base 30.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. An electronic device comprising:
a base, the base comprising a supporting board and a positioning portion; the positioning portion being located on one side of the supporting board; and
a cover secured to the base;
wherein the positioning portion abuts the supporting board and is elastically deformable to disengage from the supporting board, the cover abuts the supporting board and is rotatable relative to the base to disengage from the supporting board.

2. The electronic device of claim 1, wherein the positioning portion comprises two resilient arms and a pressing portion; the pressing portion abuts the supporting board, and the resilient arm is elastically deformable to disengage the pressing portion from the supporting board.

3. The electronic device of claim 2, wherein the pressing portion comprises a pressing surface, and the pressing surface is configured to press the supporting board.

4. The electronic device of claim 3, wherein the pressing surface is substantially arc-shaped.

5. The electronic device of claim 1, wherein the positioning portion is made of plastic material.

6. The electronic device of claim 2, wherein the pressing portion has a cross-section parallel to the supporting board, and the cross-section has an area that is smaller than an area size of the supporting board.

7. The electronic device of claim 1, wherein the cover comprises a body, the body defines a receiving slot, and the positioning portion is received in the receiving slot when the cover is closed.

8. The electronic device of claim 7, wherein the cover further comprises a pressing piece, and the pressing piece is configured to abut the supporting board.

9. The electronic device of claim 1, wherein the supporting board is made of glass material.

10. An electronic device comprising:
a base comprising a basic portion, a supporting board installed on the basic portion, and a positioning portion; the positioning portion extending from the basic portion and located on one side of the supporting board; and
a cover secured to the base;
wherein the positioning portion abuts the supporting board and is elastically deformable to disengage from the supporting board; the cover abuts the supporting board and is rotatable relative to the base to disengage from the supporting board.

11. The electronic device of claim 10, wherein the positioning portion comprises two resilient arms and a pressing portion; the pressing portion abuts the supporting board, and the two resilient arms are elastically deformable to disengage the pressing portion from the supporting board.

12. The electronic device of claim 11, wherein the pressing portion comprises a pressing surface, and the pressing surface abuts the supporting board.

13. The electronic device of claim 12, wherein the pressing surface is substantially arc-shaped.

14. The electronic device of claim 10, wherein the positioning portion is made of plastic material.

15. The electronic device of claim 11, wherein the pressing portion has a cross-section parallel to the supporting board, and the cross-section has an area that is smaller than an area size of the supporting board.

16. The electronic device of claim 10, wherein the cover comprises a body, the body defines a receiving slot, the positioning portion is received in the receiving slot when the cover is closed.

17. The electronic device of claim 16, wherein the cover further comprises a pressing piece, the pressing piece abuts the supporting board and is capable of disengaging from the supporting board by the cover rotatable.

18. The electronic device of claim 10, wherein the supporting board is made of glass material.
